(19) United States
(12) Patent Application Publication
(10) Pub. No.: US 2008/0178795 A1
(43) Pub. Date: Jul. 31, 2008

(54) Gas Bearing Spindles

(76) Inventor: Christopher John Pavey, Dorset (GB)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 11/911,444

(22) PCT Filed: Apr. 11, 2006
(86) PCT No.: PCT/GB06/01306

§ 371 Date: Dec. 27, 2007

(30) Foreign Application Priority Data
Apr. 15, 2005 (GB) 0507681.5

(51) Int. Cl. F16C 33/12; C23C 14/00

(52) U.S. Cl. 118/50; 384/100

(57) ABSTRACT

A gas bearing spindle (2) for use in processing apparatus (1), for example ion implantation apparatus. The spindle (2) has a steel bearing surface (23) and a shaft (3) coated with chrome (3a) or another hard material.

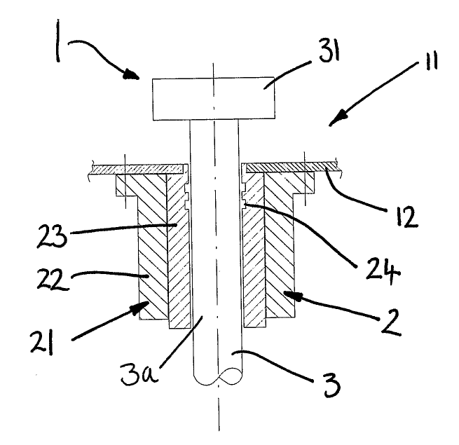

This invention relates to gas bearing spindles in particular spindles which are for use in the positioning of substrates in high vacuum ion implantation devices.

In some circumstances such a spindle needs to provide axial movement of the substrate within a high vacuum implantation chamber whereas in other circumstances it may be necessary to provide a rotational movement of the substrate or both axial and rotational movement. These different types of spindle bring with them different requirements and the present application is perhaps most applicable to spindles which are arranged to provide axial movement rather than rotational, or at least only, low speed rotational movement.

Spindles for use with high vacuum ion implantation apparatus have special requirements and/or difficulties which need to be overcome. Because of the vacuum within the chamber, there is a tendency for any particles generated due to wear within the spindle to be sucked into the high vacuum chamber. Once such particles are in the high vacuum chamber, these can serve to contaminate the environment and interfere with the ion implantation process.

This means that special consideration needs to be given in terms of the performance and characteristics of the spindle used with the apparatus.

In one existing system problems occur as traditional bronze based bearings are used in the spindle and particles from these bronze bearings generated by wear interfere with the ion implantation process within the chamber.

It is an object to the present invention to alleviate at least some of the problems associated with the prior art.

According to one aspect of the present invention there is provided a gas bearing spindle for moving a substrate within a vacuum chamber during a processing operation, the spindle comprising a shaft supported within a gas bearing sleeve portion which is a portion of a body of the spindle, the shaft being arranged for operating on a substrate disposed in the interior of the vacuum chamber and at least part of a surface of the gas bearing sleeve portion which faces the shaft being of a material with a Vickers Hardness of at least 150 HV.

The material with a Vickers Hardness of at least 150 HV may, for example, be one of: steel and a ceramic material, for example silicon nitride. The use of such materials runs against standard engineering practice but has been found surprisingly effective and preferable in the present invention as the production of contaminants that may interfere with the process within the vacuum chamber can be reduced.

The use of steel is preferable on the basis of cost and ease of manufacture. Below the expression “hard material” is used to mean a material with a Vickers Hardness of at least 150 HV for the sake of brevity.

The whole of the surface of the gas bearing sleeve portion which faces the shaft may be of hard material. The whole of the gas bearing sleeve portion may be of hard material. The whole of the surface of the gas bearing sleeve portion which faces the shaft may be of steel. The whole of the gas bearing sleeve portion may be of steel.

At least a portion of the body may be arranged to be disposed outside of the vacuum chamber. The shaft may be arranged to penetrate from the exterior to the interior of the vacuum chamber.

Preferably at least a portion of the shaft that runs within the gas bearing sleeve portion is coated with a material which is harder than the material of surface of the gas bearing sleeve portion. The coating may comprise a material plated onto the shaft. Preferably at least that portion of the shaft that runs within the gas bearing sleeve portion is plated with at least one of: chrome, Armolloy chrome plating, and nickel.

Preferably the shaft is of steel. Of course a steel shaft may be coated as discussed above. The use of a steel shaft plated with chrome or thin dense chrome plating is most preferred. The thin dense chrome may be micronodular and low friction. The thin dense chrome plating may be Armolloy (trade mark) chrome plating. The chrome plating may have a hardness of say 900 HV (Vickers Hardness) or say 1400 HV (Vickers Hardness) in the case of thin dense chrome plating.

The gas bearing spindle may be arranged to allow axial movement of the shaft relative to the sleeve portion. The gas bearing spindle may be arranged to allow rotary movement of the shaft relative to the sleeve portion.

The gas bearing spindle may comprise contactless sealing means allowing maintenance of a vacuum in the vacuum chamber.

The surface of the bearing sleeve portion may comprise a plurality of axially spaced circumferential grooves which are connectable to at least one vacuum pump. Such an arrangement can help provide sealing of the vacuum chamber.

According to another aspect of the present invention there is provided processing apparatus comprising a vacuum chamber and a gas bearing spindle as defined above in which the main body of the spindle is mounted to the exterior of the vacuum chamber and the shaft penetrates through a wall of the chamber from the exterior to the interior of the chamber.

The processing apparatus may be a wafer processing apparatus. The processing apparatus may be an ion implantation apparatus.

According to a further aspect of the present invention there is provided a method of operating a processing apparatus as defined above in which copper wafer substrates are processed.

According to a further aspect of the present invention there is provided a gas bearing spindle for moving a substrate within a vacuum chamber during a processing operation, the spindle comprising a shaft supported within a gas bearing sleeve portion which is a portion of a body of the spindle, the shaft being arranged for operating on a substrate disposed in the interior of the vacuum chamber and the shaft and at least part of a surface of the gas bearing sleeve portion which faces the shaft being of hard materials.

According to a further aspect of the present invention there is provided a gas bearing spindle for moving a substrate within a vacuum chamber during a processing operation, the spindle comprising a shaft supported within a gas bearing sleeve portion which is a portion of a body of the spindle, the shaft being arranged for operating on a substrate disposed in the interior of the vacuum chamber and the shaft and at least part of a surface of the gas bearing sleeve portion which faces the shaft being of materials which are at least as hard as steel.

According to another aspect of the present invention there is provided a gas bearing spindle for moving a substrate within a vacuum chamber during a processing operation, the spindle comprising a shaft supported within a gas bearing sleeve portion which is a portion of a body of the spindle, the shaft being arranged for operating on a substrate disposed in the interior of the vacuum chamber and at least part of a surface of the gas bearing sleeve portion which faces the shaft being of steel.

According to another aspect of the present invention there is provided a gas bearing spindle for moving a substrate within a vacuum chamber during a processing operation, the spindle comprising a shaft supported within a gas bearing sleeve portion which is a portion of a body of the spindle, the shaft being arranged for operating on a substrate disposed in the interior of the vacuum chamber and at least part of a surface of the gas bearing sleeve portion which faces the shaft being of ceramic material.

According to another aspect of the present invention there is provided a gas bearing spindle for moving a substrate within a vacuum chamber during a processing operation, the spindle comprising a shaft supported within a gas bearing sleeve portion which is a portion of a body of the spindle, the shaft being arranged for operating on a substrate disposed in the interior of the vacuum chamber and at least part of a surface of the gas bearing sleeve portion which faces the shaft being of silicon nitride.

Embodiments of the present invention will now be described, by way of example only, with reference to the accompanying drawing which schematically shows a gas bearing spindle installed in an ion implantation apparatus.

The drawing schematically shows part of an ion implantation apparatus 1 which incorporates a linear gas bearing spindle 2.

The ion implantation apparatus 1 comprises generally conventional implantation equipment which is not shown in detail in the drawings nor described in detail in the present application as it is not pertinent to the present invention.

It is important to note however that the ion implantation apparatus comprises a high vacuum chamber 11 (a part of which is shown in the drawing) which is defined by a chamber wall 12 (only part of which is shown in the drawing). The spindle 2 is mounted on the chamber wall 12.

The linear gas bearing spindle 2 comprises a body 21 which itself comprises a main body portion 22, and mounted within this main body portion 22, a gas bearing sleeve portion 23.

Mounted in the body 21 there is a shaft 3 which is arranged for axial movement within the body 21 and is supported by the gas bearing sleeve portion 23.

The shaft 3 passes from the exterior of the high vacuum chamber 11 to the interior of the high vacuum chamber 11 and thus passes through (or penetrates through) the wall 12 of the high vacuum chamber 11. The end of the shaft 3 which is disposed within the high vacuum chamber 11, is provided with a mounting portion 31 on which a substrate which is to be subjected to the ion implantation process may be mounted.

The shaft 3 is supported by the bearing from one end, that is to say the shaft 3 is cantilevered.

It will be appreciated that in a typical implementation, the shaft 3 will be generally cylindrical as will be spindle 2 as a whole, with the body 21, main body portion 22, and sleeve portion 23 being generally annular.

It will be noted that such configuration allows, at least in principal, for the shaft 3 to be rotated relative to the body 21 so that a sample carried by the shaft might be rotated within the chamber 11 as well as moved axially. However, in the present embodiment, linear movement of the shaft 3 is all that is required.

As there is a high vacuum within the chamber 11, and the linear gas bearing spindle 2 provides a potential gas flow path from the exterior of the chamber 11 to the interior of the chamber 11, there will be a tendency for gas to leak into the chamber 11 via the spindle 2.

However the gas bearing sleeve portion 23 is arranged to minimise such leakage. In particular, a plurality of circumferential grooves 24 are provided on the inner curved surface of the annular sleeve portion 23 and these are connected to respective vacuum pumps (not shown) to provide a gradual stepping down in pressure from atmospheric pressure at one end of the spindle 2 to the high vacuum within the chamber 11 at the other end of the spindle 2. The details of such an arrangement for providing a suitable seal within the spindle 2 can be found, for example, in U.S. Pat. No. 4,726,689.

As alluded to in the introduction, in a conventional spindle of the type described above (for example the one described in U.S. Pat. No. 4,726,689), it would be usual to make the bearing surfaces of a soft material such as bronze. This is the case even where the bearing is a gas bearing, so if operated properly and without malfunction, there will be no contact between the shaft 3 and the bearing sleeve portion 23. In such cases it is also conventional to use a steel shaft 3 or a chrome plated steel shaft 3 such that if there is contact between the shaft 3 and the bearing 23, the bearing 23 will wear in a progressive and predictable way with harder steel and/or chrome particles, if present, embedding into the bronze, rather than causing catastrophic failure.

Normally such wear is acceptable, but in the present circumstances problems can occur if particles caused by the wear of the bearing are sucked into the chamber 11. In the chamber 11, the particles may interfere with the ion implantation process.

This issue has caused a significant problem for the use of spindles such as shown in U.S. Pat. No. 4,726,689 where certain types of ion implantation processes are being carried out. One possible way to overcome these problems is to use graphite as an alternative bearing material as this meets the normal requirement of being soft and also has a nature which is generally inert in ion implantation processes. As such, any graphite which enters the chamber will not tend to interfere with the process.

However the use of graphite is undesirable since it is difficult to process in manufacture and structurally weak.

Therefore a different alternative is desirable. In the present embodiment, the gas bearing sleeve portion 23 is made of steel, (in particular, in this case, Austenitic stainless steel eg 303S21 (BS 970), which is non magnetic and has a hardness of 183 HV (Vickers Hardness)), as indeed, is the remainder of the body 21. This runs contrary to normal engineering practice in which a soft bearing material should be chosen. However satisfactory results have surprisingly been achieved with this design.

In the present embodiment the shaft 3, or at least that portion of the shaft 3 which passes through the sleeve portion 23 at some point in the shaft's travel, is plated with chrome 3a. In alternative the shaft 3 maybe coated with thin dense chrome plating (for example Armolloy (Trade Mark) chrome plating). This helps to give the shaft 3 a very precise and smooth finish which helps to minimise any wear in the sleeve portion 23. Whilst the choice of steel goes against engineering practice, as a bearing material it has the advantage that, if there is wear and particles of steel enter into the chamber 11 these will not interfere with an ion implantation process where a copper substrate is used. This is in contrast to the situation where a bronze bearing material is used.

It is also possible to use other non-conventional bearing materials such as silicon nitride or other ceramic materials. The use of a very hard but very smooth shaft coating and a hard bearing material can serve to reduce the amount of wear particles that are produced.

There are perhaps some limitations as to the axial speed of shaft 3 movement which the present embodiment can tolerate and similarly limits on the rotational speed which could be tolerated if the shaft 3 is set up to be rotatingly driven relative to the body 21. Precise limits for these speeds could be determined simply enough by carrying out straightforward tests.

In an alternative the face of the bearing which faces the shaft may also be coated with chrome or Armolloy chrome plating.

1. A gas bearing spindle for moving a substrate within a vacuum chamber during a processing operation, the spindle comprising a generally cylindrical shaft supported within a generally annular gas bearing sleeve portion which is a portion of a body of the spindle, the shaft being arranged for operating on a substrate disposed in the interior of the vacuum chamber and at least part of a surface of the gas bearing sleeve portion which faces the shaft being of a material with a Vickers Hardness of at least 150 HV wherein the gas bearing spindle is arranged to allow axial and rotary movement of the shaft relative to the sleeve portion and, the material with a Vickers Hardness of at least 150 HV is steel and at least a portion of the shaft that runs within the gas bearing sleeve portion is coated with a material which is harder than the material of said at least part of the surface of the gas bearing sleeve portion.

2. A gas bearing spindle according to claim 1 in which the whole of the surface of the gas bearing sleeve portion which faces the shaft is of material with a Vickers Hardness of at least 150 HV.

3. A gas bearing spindle according to claim 1 in which the whole of the gas bearing sleeve portion is of material with a Vickers Hardness of at least 150 HV.

4. A gas bearing spindle according to claim 1 in which at least a portion of the body is arranged to be disposed outside of the vacuum chamber.

5. A gas bearing spindle according to claim 4 in which the shaft is arranged to penetrate from the exterior to the interior of the vacuum chamber.

6. A gas bearing spindle according to claim 5 in which a free end of the shaft is arranged for supporting the substrate.

7. A gas bearing spindle according to claim 1 in which the coating comprises a material plated onto the shaft.

8. A gas bearing spindle according to claim 7 in which at least that portion of the shaft that runs within the gas bearing sleeve portion is plated with at least one of: chrome, thin dense chrome plating, and nickel.

9. A gas bearing spindle according to claim 8 in which at least that portion of the shaft that runs within the gas bearing sleeve portion is plated with the thin dense chrome plating.

10. A gas bearing spindle according to claim 8 in which the chrome plating has a hardness of about 900 HV (Vickers Hardness) or about 1400 HV (Vickers Hardness) in the case of thin dense chrome plating.

11. A gas bearing spindle according to claim 1 in which the shaft is of steel.

12. A gas bearing spindle according to claim 1 which comprises contactless sealing means allowing maintenance of a vacuum in the vacuum chamber.

13. A gas bearing spindle according to claim 1 in which the surface of the bearing sleeve portion comprises a plurality of axially spaced circumferential grooves which are connectable to at least one vacuum pump.

14. Processing apparatus comprising a vacuum chamber and a gas bearing spindle according to claim 1 in which the main body of the spindle is mounted to the exterior of the vacuum chamber and the shaft penetrates through a wall of the chamber from the exterior to the interior of the chamber.

15. Processing apparatus according to claim 14 in which one end of the shaft is disposed within the interior of the chamber.

16. Processing apparatus according to claim 14 which is wafer processing apparatus.

17. Processing apparatus according to claim 14 which is ion implantation apparatus.

18. A method of operating a processing apparatus according to claim 14 in which process, copper wafer substrates are processed.

19. A gas bearing spindle for moving a substrate within a vacuum chamber during a processing operation, the spindle comprising a shaft supported for axial and rotary movement within a gas bearing sleeve portion which is a portion of a body of the spindle, the shaft being arranged for operating on a substrate disposed in the interior of the vacuum chamber and at least part of a surface of the gas bearing sleeve portion which faces the shaft being of steel, wherein at least a portion of the shaft that runs within the gas bearing sleeve portion is coated with a material which is harder than the material of the surface of the gas bearing sleeve portion.

20. A gas bearing spindle for moving a substrate within a vacuum chamber during a processing operation, the spindle comprising a shaft supported for axial and rotary movement within a gas bearing sleeve portion which is a portion of a body of the spindle, the shaft being arranged for operating on a substrate disposed in the interior of the vacuum chamber and at least part of a surface of the gas bearing sleeve portion which faces the shaft being of ceramic material.

21. A gas bearing spindle for moving a substrate within a vacuum chamber during a processing operation, the spindle comprising a shaft supported for axial and rotary movement within a gas bearing sleeve portion which is a portion of a body of the spindle, the shaft being arranged for operating on a substrate disposed in the interior of the vacuum chamber and at least part of a surface of the gas bearing sleeve portion which faces the shaft being of silicon nitride.
